(19) United States
(12) Patent Application Publication
(10) Pub. No.: US 2026/0215026 A1
(43) Pub. Date: Jul. 23, 2026

(54) PHOTOVOLTAIC CELL, CELL STRING AND PHOTOVOLTAIC MODULE

(71) Applicants: JIANGSU RUNERGY CENTURY PHOTOVOLTAIC TECHNOLOGY CO., LTD., Yancheng City (CN); JIANGSU RUNERGY YUEDA PHOTOVOLTAIC TECHNOLOGY CO., LTD., Yancheng Ctiy (CN)

(72) Inventors: Rulong Chen, Yancheng City (CN); Zhuojian Yang, Yancheng City (CN); Chuanhong Hu, Yancheng City (CN); Longzhong Tao, Yancheng City (CN)

(21) Appl. No.: 19/409,346

(22) Filed: Dec. 4, 2025

(30) Foreign Application Priority Data
Jan. 22, 2025 (CN) 202510105161.5

(51) Int. Cl. H10F 77/20

(52) U.S. Cl. CPC H10F 77/219

(57) ABSTRACT

The present disclosure provides a photovoltaic cell, a cell string and a photovoltaic module. The photovoltaic cell includes a positive electrode and a negative electrode. At least one of the positive electrode and the negative electrode includes a plurality of sub-electrodes spaced apart from each other, so that the photovoltaic cell includes a plurality of sub-cells connected in parallel, and each of the plurality of sub-electrodes serves as an electrode of a corresponding sub-cell of the plurality of sub-cells.

### CROSS-REFERENCE TO RELATED APPLICATIONS

The present application is based on and claims priority from Chinese patent application No. 202510105161.5 filed on Jan. 22, 2025, the entire disclosure of which is incorporated herein by reference.

### TECHNICAL FIELD

The present disclosure relates to the technical field of new energy, and particularly relates to a photovoltaic cell, a cell string, and a photovoltaic module.

### BACKGROUND

As a device capable of directly converting solar energy into electric energy, the photovoltaic cell functions based on the photovoltaic effect. Essentially, a photovoltaic cell is a large-area p-n junction, similar to a large-area diode. When the photovoltaic cell is irradiated, photogenerated carriers are separated, and then, the photovoltaic cell becomes a reverse-biased diode, where electric energy is output from an anode of the diode. Currently, photovoltaic modules are faced with a serious problem, i.e., the hot spot effect. A photovoltaic module may be blocked by a local shadow in an actual use scene, causing a hot spot effect on the blocked photovoltaic cell, which may greatly reduce the power generation efficiency, and significantly shorten the service life of the photovoltaic module.

### SUMMARY OF THE INVENTION

An embodiment of the present disclosure provides a photovoltaic cell, including: a positive electrode and a negative electrode, wherein at least one of the positive electrode and the negative electrode is divided into a plurality of sub-electrodes spaced apart from each other, so that the photovoltaic cell includes a plurality of sub-cells connected in parallel, and each of the plurality of sub-electrodes serves as an electrode of a corresponding sub-cell of the plurality of sub-cells.

In some embodiments, the plurality of sub-electrodes are separated by a distance of 0.1 mm to 3 mm.

In some embodiments, a sub-electrode of the positive electrode includes a positive busbar and positive finger lines electrically connected to the positive busbar.

In some embodiments, the positive finger lines in each sub-cell are separated from each other.

In some embodiments, every two positive finger lines in each sub-cell are connected end to end.

In some embodiments, every three or more or all positive finger lines in each sub-cell are connected end to end.

In some embodiments, the plurality of sub-electrodes are separated by a distance equal to a pitch between the positive finger lines.

In some embodiments, a sub-electrode of the negative electrode includes a negative busbar and negative finger lines electrically connected to the negative busbar.

In some embodiments, the negative finger lines in each sub-cell are separated from each other.

In some embodiments, every two negative finger lines in each sub-cell are connected end to end.

In some embodiments, every three or more or all negative finger lines in each sub-cell are connected end to end.

In some embodiments, the plurality of sub-electrodes are separated by a distance equal to a pitch between the negative finger lines.

In some embodiments, when each of the positive electrode and the negative electrode is divided into a plurality of sub-electrodes spaced apart from each other, the sub-electrodes of the positive electrode are arranged in one-to-one correspondence with the sub-electrodes of the negative electrode.

Another embodiment of the present disclosure provides a cell string, including a plurality of photovoltaic cells connected in series, wherein each of the plurality of photovoltaic cells is the photovoltaic cell described above.

Another embodiment of the present disclosure provides a photovoltaic module, including a plurality of cell strings electrically connected with each other, wherein each of the plurality of cell strings is the cell string described above.

In the present disclosure, the positive electrode and/or the negative electrode of the photovoltaic cell include a plurality of sub-electrodes to form a plurality of sub-cells connected in parallel, so that when a photovoltaic module consisting of such photovoltaic cells is partially blocked (e.g., by leaves, bird droppings, and the like), a certain sub-cell in the blocked photovoltaic cell does not generate electricity, thereby greatly reducing the influence of hot spots on the photovoltaic module.

### BRIEF DESCRIPTION OF THE DRAWINGS

FIG. 1 shows a schematic side view of an existing photovoltaic cell.

FIG. 2 shows a schematic top view of positive busbars and positive finger lines at a positive electrode of an existing photovoltaic cell.

FIG. 3 shows a schematic top view of negative busbars and negative finger lines at a negative electrode of an existing photovoltaic cell.

FIG. 4 shows a schematic side view of a photovoltaic cell according to some embodiments of the present disclosure.

FIG. 5 shows a schematic side view of a photovoltaic cell according to some embodiments of the present disclosure.

FIG. 6 shows a schematic side view of a photovoltaic cell according to some embodiments of the present disclosure.

FIG. 7a shows a schematic connection relationship of cell strings in a photovoltaic module according to some embodiments of the present disclosure.

FIG. 7b shows a schematic connection relationship of cell strings in a photovoltaic module according to some embodiments of the present disclosure.

FIG. 7c shows a schematic equivalent model of cell strings in a photovoltaic module according to some embodiments of the present disclosure.

FIG. 8 shows a schematic top view of positive busbars and positive finger lines at a positive electrode of a photovoltaic cell according to some embodiments of the present disclosure.

FIG. 9 shows a schematic top view of positive busbars and positive finger lines at a positive electrode of a photovoltaic cell according to some embodiments of the present disclosure.

FIG. 10 shows a schematic top view of positive busbars and positive finger lines at a positive electrode of a photovoltaic cell according to some embodiments of the present disclosure.

FIG. 11 shows a schematic top view of negative busbars and negative finger lines at a negative electrode of a photovoltaic cell according to some embodiments of the present disclosure.

FIG. 12 shows a schematic top view of negative busbars and negative finger lines at a negative electrode of a photovoltaic cell according to some embodiments of the present disclosure.

FIG. 13 shows a schematic top view of negative busbars and negative finger lines at a negative electrode of a photovoltaic cell according to some embodiments of the present disclosure.

FIG. 14 shows a schematic partially enlarged view of positive busbars and positive finger lines at a positive electrode of a photovoltaic cell according to some embodiments of the present disclosure.

### DETAIL DESCRIPTION OF THE EMBODIMENTS

To improve understanding of the technical solution of the present disclosure for those skilled in the art, the technical solution of the present disclosure will be described below in detail in conjunction with the accompanying drawings.

Exemplary embodiments will be described more sufficiently below with reference to the accompanying drawings, but which may be embodied in different forms and should not be construed as limited to the embodiments set forth herein. Rather, these embodiments are provided so that the present disclosure will be thorough and complete, and will fully convey the scope of the present disclosure to those skilled in the art.

The embodiments of the present disclosure and features thereof may be combined with each other as long as they are not contradictory.

As used herein, the term “and/or” includes any and all combinations of one or more of the associated listed items.

The terminology used herein is for the purpose of describing specific embodiments only and is not intended to limit the present disclosure. As used herein, the singular forms “a”, “an” and “the” are intended to include the plural forms as well, unless the context clearly indicates otherwise. It will be further understood that as used herein, the terms “comprise” and/or “consist of . . . ” specify the presence of the stated features, integers, steps, operations, elements, and/or components, but do not preclude the presence or addition of one or more other features, integers, steps, operations, elements, components, and/or groups thereof.

Embodiments described herein may be described with reference to plan and/or sectional views in idealized representations of the present disclosure. Accordingly, the example illustrations may be modified in accordance with the manufacturing process and/or the tolerance. Therefore, the embodiments are not limited to the embodiments shown in the accompanying drawings, but further include modifications of configurations formed based on a manufacturing process. Therefore, the regions illustrated in the accompanying drawings have schematic properties, and the shapes of the regions shown in the accompanying drawings illustrate specific shapes of regions of elements, but are not intended to be limiting.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the existing art and the present disclosure, and will not be interpreted in an idealized or overly formal sense unless expressly so defined herein.

In the existing design scheme of the photovoltaic module, photovoltaic cells are typically connected in series into 3 or 6 strings, and every one or two photovoltaic cell strings are connected in parallel with a bypass diode of the opposite polarity. Generally, one photovoltaic module includes 3 bypass diodes. However, this design has notable defects in handling a hot spot impact. When the photovoltaic module is partially blocked, the blocked photovoltaic cell stops generating electricity, and no current is generated. At this time, the bypass diode connected in parallel with the photovoltaic cell string starts working to lead out current generated by the other 2 photovoltaic cell strings which are not blocked. Meanwhile, other photovoltaic cells in the blocked photovoltaic cell string will supply power to the blocked photovoltaic cell in a reverse direction, causing the blocked photovoltaic cell to generate heat, and consuming the electric energy generated by the cell string. Therefore, once local blocking occurs, 1 photovoltaic cell string will stop working, and the overall power generation capacity of the photovoltaic module will be reduced instantaneously by one third or one sixth. More seriously, the blocked photovoltaic cell generating heat may accelerate the aging of the packaging material, and even cause serious safety accidents such as fire, which seriously influences the power generation capacity, reliability and safety of the photovoltaic module.

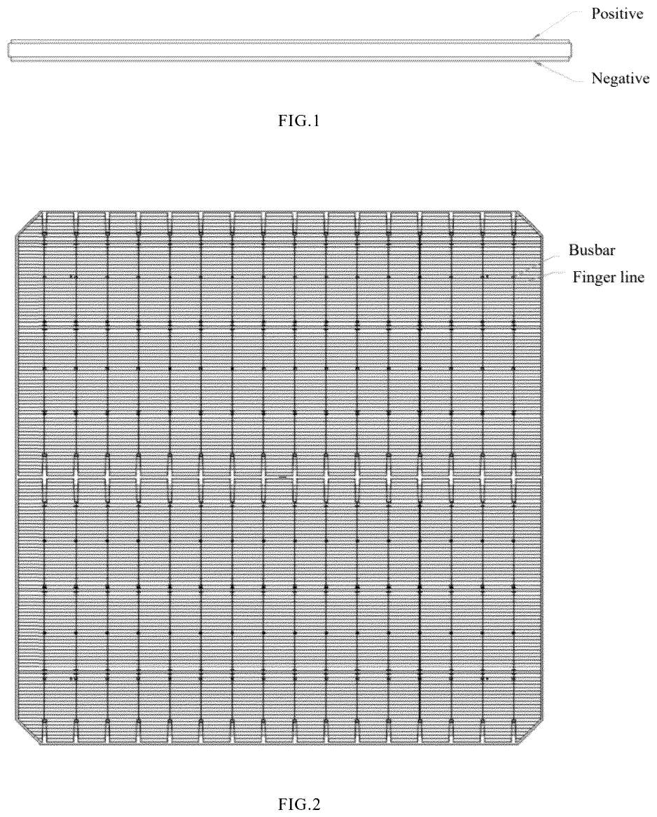

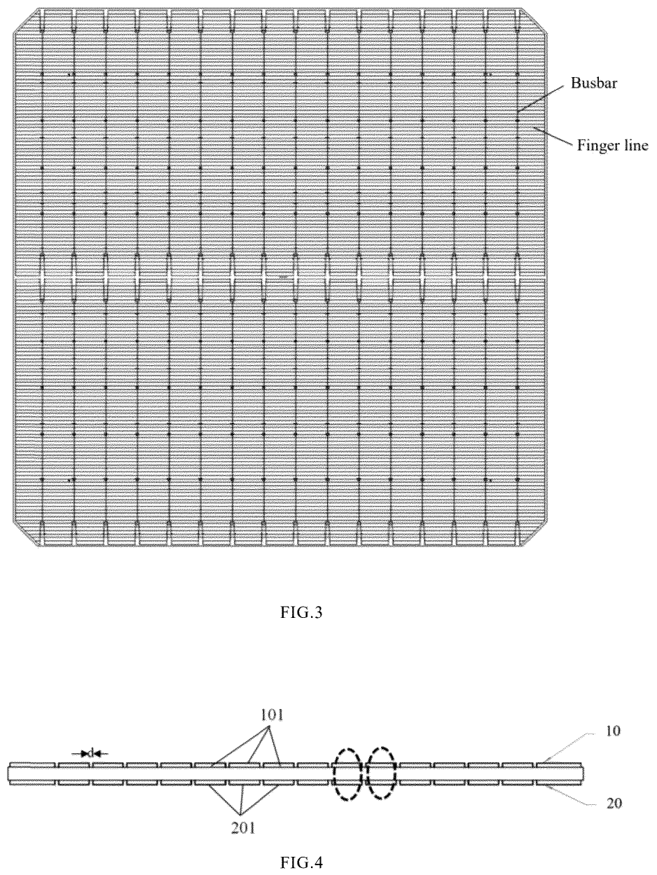

FIG. 1 is a schematic side view of an existing photovoltaic cell, FIG. 2 is a schematic top view of positive busbars and positive finger lines at a positive electrode of an existing photovoltaic cell, and FIG. 3 is a schematic top view of negative busbars and negative finger lines at a negative electrode of an existing photovoltaic cell. As shown in FIGS. 1 to 3, both a positive electrode and a negative electrode of the existing photovoltaic cell are continuous, and positive finger lines and negative finger lines substantially span the whole photovoltaic cell. Such photovoltaic cells are connected in series to form a cell string, and then a plurality of cell strings is connected in series and in parallel based on requirements to obtain a photovoltaic cell array, which is then packaged to form a complete photovoltaic module. Typically, every one or two photovoltaic cell strings are connected in parallel with a bypass diode of the opposite polarity, and when the photovoltaic module is partially blocked, the blocked photovoltaic cell stops generating electricity, and no current is generated. At this time, the bypass diode connected in parallel with the photovoltaic cell string starts working to lead out current generated by the other 2 photovoltaic cell strings which are not blocked. Meanwhile, other photovoltaic cells in the blocked photovoltaic cell string will supply power to the blocked photovoltaic cell in a reverse direction, causing the blocked photovoltaic cell to generate heat, and consuming the electric energy generated by the cell string. Therefore, once local blocking occurs, 1 photovoltaic cell string will stop working, and the overall power generation capacity of the photovoltaic module will be reduced instantaneously by one third or one sixth.

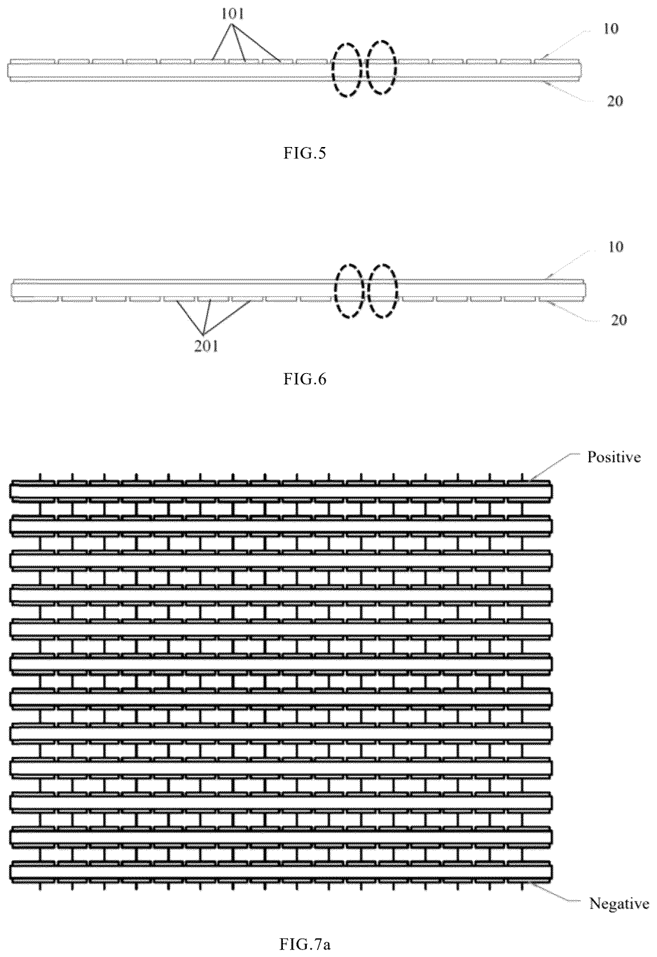

An embodiment of the present disclosure provides a photovoltaic cell, including a positive electrode 10 and a negative electrode 20. The positive electrode 10 and the negative electrode 20 are configured to collect current generated by the photovoltaic cell. In some embodiments, at least one of the positive electrode 10 and the negative electrode 20 includes a plurality of sub-electrodes 101/201 spaced apart from each other. FIG. 4 shows an embodiment in which the positive electrode 10 and the negative electrode 20 are each divided into a plurality of sub-electrodes, FIG. 5 shows an embodiment in which the positive electrode 10 is divided into a plurality of sub-electrodes 101, and FIG. 6 shows an embodiment in which the negative electrode 20 is divided into a plurality of sub-electrodes 201. In this manner, the photovoltaic cell includes a plurality of sub-cells (as indicated by the dashed boxes in FIGS. 4 to 6), and each of the plurality of sub-electrodes serves as an electrode of a corresponding sub-cell of the plurality of sub-cells. In some embodiments, the plurality of sub-cells may be connected in parallel by solder strips. In some embodiments, the positive electrode 10 and the negative electrode 20 of the present disclosure may be formed by screen printing, but this is merely exemplary and other suitable methods may be employed.

Additionally, it should be understood that although FIG. 4 shows the positive electrode 10 and the negative electrode 20 divided into 16 sub-electrodes 101/201, this is merely exemplary, and other suitable numbers of sub-electrodes may be included, e.g., 4, 8, 12, 20, 24, and the like, and preferably, an integer selected from 4 to 24.

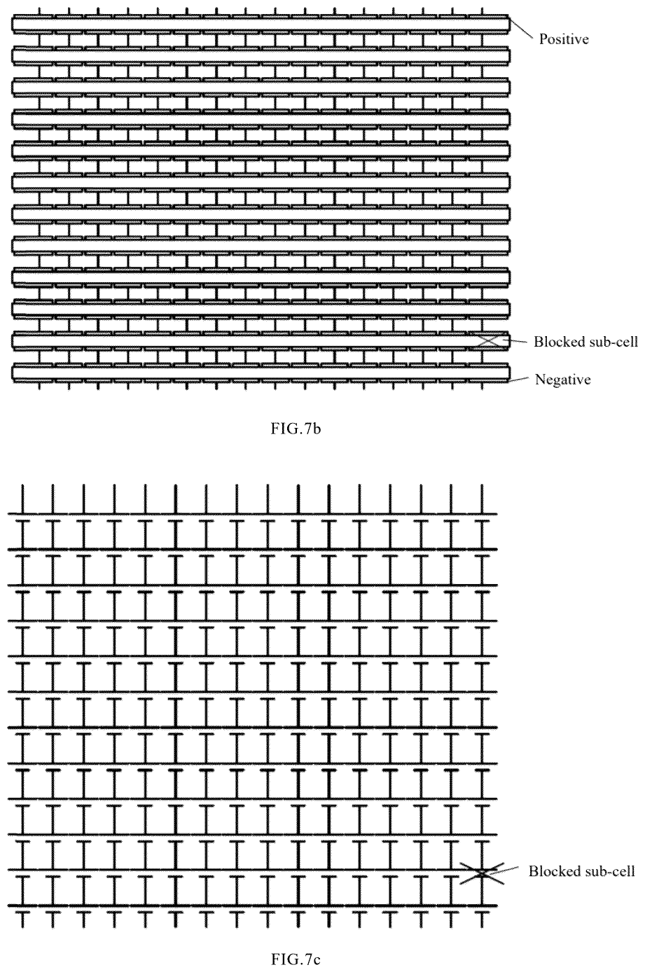

FIG. 7a shows a schematic connection relationship of cell strings in a photovoltaic module according to some embodiments of the present disclosure, FIG. 7b shows a schematic connection relationship of cell strings in a photovoltaic module according to some embodiments of the present disclosure, and FIG. 7c shows a schematic equivalent model of cell strings in a photovoltaic module according to some embodiments of the present disclosure. When the photovoltaic module consisting of the photovoltaic cells of the present disclosure is partially blocked, only the sub-cell at a blocked position in the blocked photovoltaic cell stop generating electricity, while most sub-cells can still generate electricity normally. As a result, the photovoltaic module can be ensured to keep higher power generation capacity and reliability even when being partially blocked.

According to the photovoltaic module design of the present disclosure, once local blocking occurs, only 1 photovoltaic cell locally fails (i.e., only some of the sub-cells fail), and the reduction of the power generation capability is significantly reduced to only a few percent, which is obviously superior to the reduction of one third or one sixth in the existing art. In the case that photovoltaic cells are connected in series in a cell string of the photovoltaic module, an output current of the cell string will be reduced as long as one photovoltaic cell is blocked, where the output current of the cell string is limited by the lowest output current. In some existing technologies, a bypass diode of the opposite polarity is connected in parallel with the cell string to reduce the influence of a single blocked photovoltaic cell on the cell string, but at the cost of reducing the power generation performance of the cell string. According to the solution of the present disclosure, through dividing electrodes of the photovoltaic cell in the cell string, the photovoltaic cell is divided into a plurality of sub-cells connected in parallel, and when blocking occurs, only the corresponding sub-cell does not generate electricity, while other sub-cells generate electricity normally, so that the influence on the output current of the cell string can be reduced. In addition, since the heating temperature of the blocked photovoltaic cell is greatly reduced, the aging of the packaging material is significantly reduced, the service life of the photovoltaic module is prolonged, and the reliability of the whole photovoltaic module system is improved. In addition, the present disclosure can be well compatible with the existing manufacturing procedures of photovoltaic cells and photovoltaic modules, while achieving an innovative design mainly on the metallization of photovoltaic cells, where a single photovoltaic cell is divided into a plurality of sub-cells through a special pattern, thereby effectively saving the cost of slurry for forming electrodes.

In some embodiments, the plurality of sub-electrodes 101 and the plurality of sub-electrodes 201 are both separated by a distance d of 0.1 mm to 3 mm. In this range of the distance d, a higher current collection efficiency can be achieved. If the distance d is too small, the density of sub-electrodes will be too high, which will not bring about any significant change in the current collection efficiency while causing waste of slurry. If the distance d is too large, the current collection efficiency will be affected, and the power generation efficiency of the photovoltaic module will be reduced. In some embodiments, the sub-electrode 101 includes a positive busbar 1011 and positive finger lines 1012. The positive busbar 1011 and the positive finger lines 1012 are electrically connected to collect current generated by the photovoltaic cell. In some embodiments, the sub-electrode 201 includes a negative busbar 2011 and negative finger lines 2012. The negative busbar 2011 and the negative finger lines 2012 are electrically connected to collect current generated by the photovoltaic cell. In some embodiments, the plurality of sub-electrodes 101 are separated by a distance d equal to a pitch between the positive finger lines 1012. In some embodiments, the plurality of sub-electrodes 201 are separated by a distance equal to a pitch between the negative finger lines 2012. When the sub-electrodes of the positive electrode are separated by a distance equal to the pitch between the positive finger lines, or the sub-electrodes of the negative electrode are separated by a distance equal to the pitch between the negative finger lines, an optimal current collection efficiency can be correspondingly achieved.

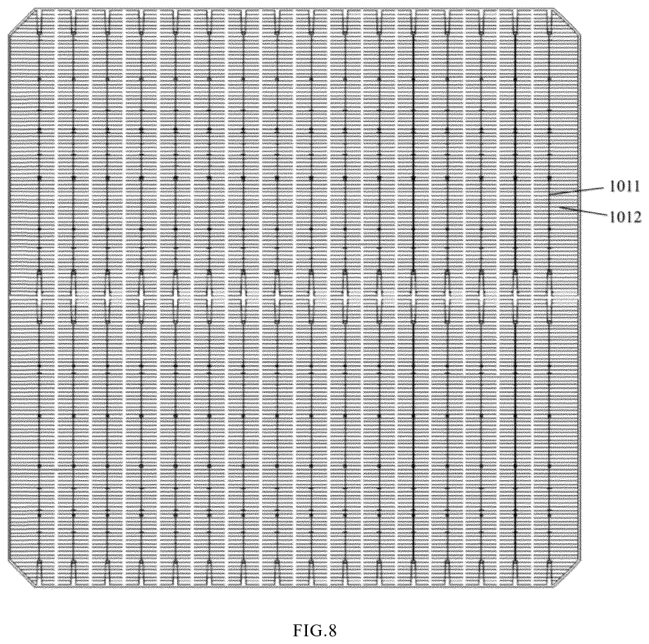

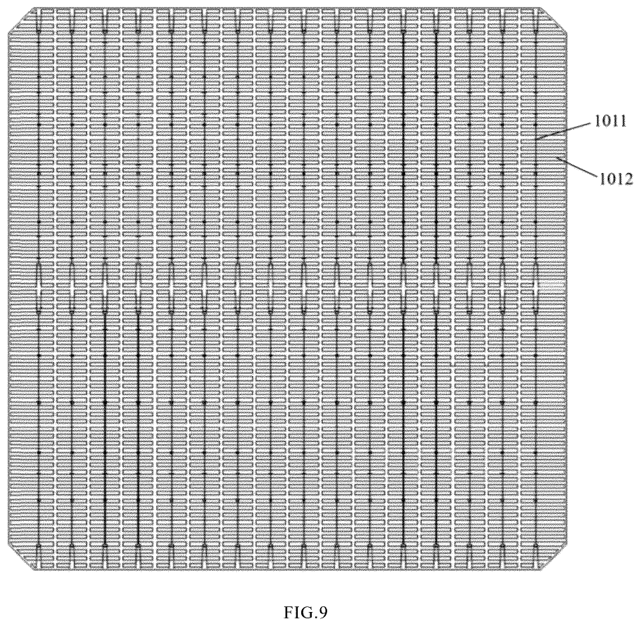

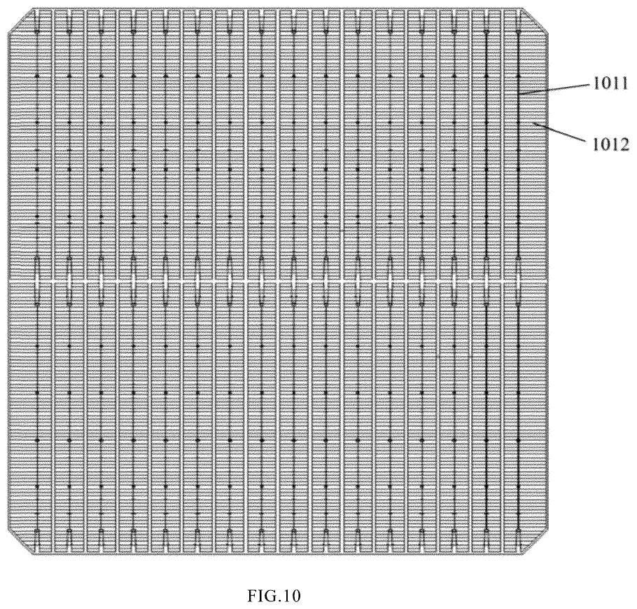

In some embodiments, as shown in FIG. 8, the positive finger lines 1012 in each sub-cell are separated from each other. That is, ends of adjacent positive finger lines 1012 are disconnected. In some embodiments, as shown in FIG. 9, every two positive finger lines 1012 in each sub-cell are connected end to end. Referring to FIG. 14, when some of the positive finger lines 1012 are damaged or disconnected (shown by the black dot in FIG. 14), current can still flow to the positive busbar 1011 in the arrow direction at both sides of the black dot, so that the problem that the current away from the positive busbar 1011 cannot be collected due to the disconnected single positive electrode finger line 1012 can be avoided, thereby improving the reliability of the corresponding sub-cell. In some embodiments, every three or more or all positive finger lines 1012 in each sub-cell are connected end to end. As shown in FIG. 9, all positive finger lines 1012 in each sub-cell are connected end to end. This structure of the positive finger lines 1012 in FIG. 9 may have an effect similar to that in FIG. 8, thereby improving the reliability of the corresponding sub-cell. However, compared with FIG. 8, the amount of slurry, generally silver slurry, used for the positive finger lines 1012 is increased, which may increase the manufacturing cost to some extent. Therefore, while ensuring the current collection effect, the structure of the positive electrode finger line 1012 in FIG. 8 can also save the cost to some extent.

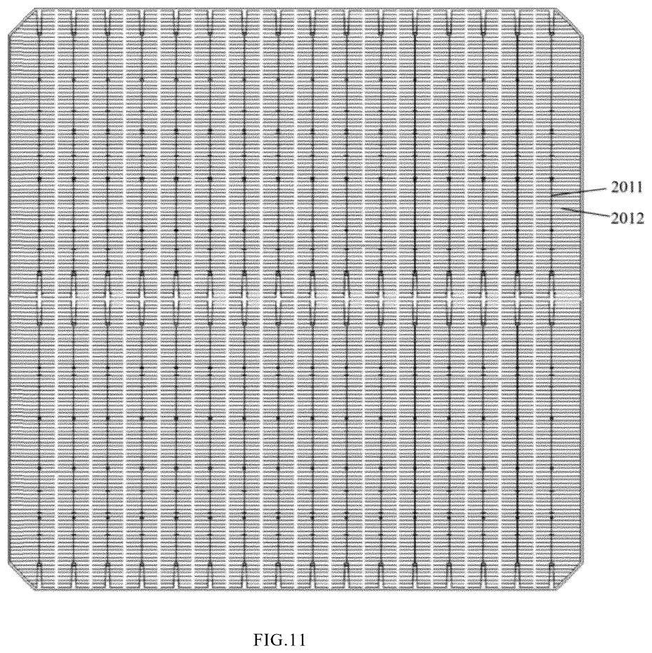

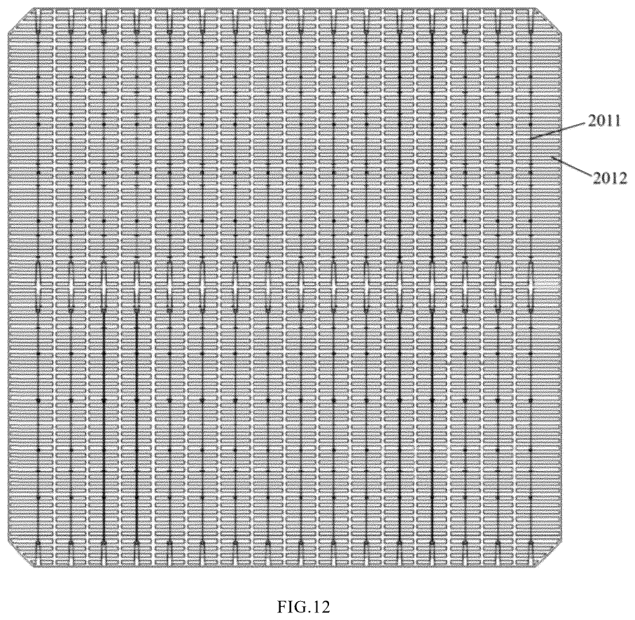

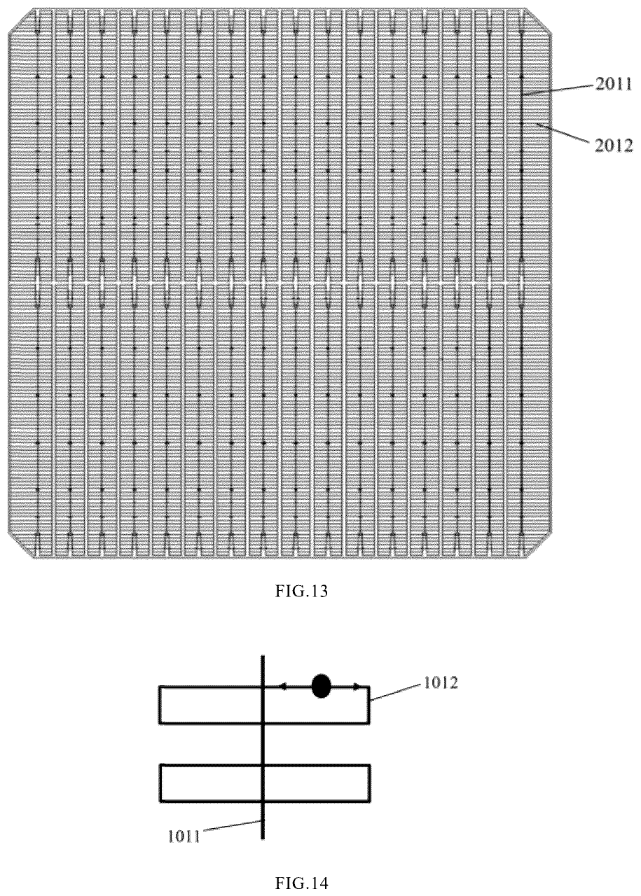

In some embodiments, as shown in FIG. 11, the negative finger lines 2012 in each sub-cell are separated from each other. In some embodiments, as shown in FIG. 12, every two negative finger lines 2012 in each sub-cell are connected end to end. It should be appreciated that the structure of the negative finger lines 2012 shown in FIG. 12 may have an effect similar to the structure of the positive finger lines 1012 in FIG. 9, thereby improving the reliability of the corresponding sub-cell. In some embodiments, every three or more or all negative finger lines 2012 in each sub-cell are connected end to end. As shown in FIG. 13, all negative finger lines 2012 in each sub-cell are connected end to end. This structure of the negative finger lines 2012 in FIG. 13 may have an effect similar to that in FIG. 12, thereby improving the reliability of the corresponding sub-cell. However, compared with FIG. 12, the amount of slurry, generally silver slurry, used for the negative finger lines 2012 is increased, which may increase the manufacturing cost to some extent.

In some embodiments, as shown in FIG. 4, when each of the positive electrode 10 and the negative electrode 20 is divided into a plurality of sub-electrodes spaced apart from each other, the sub-electrodes 101 of the positive electrode 10 are arranged in one-to-one correspondence with the sub-electrodes 201 of the negative electrode 20.

In some embodiments, the present disclosure provides a cell string, including a plurality of photovoltaic cells connected in series, where each of the plurality of photovoltaic cells is the photovoltaic cell discussion above.

In some embodiments, the present disclosure provides a photovoltaic module, including a plurality of cell strings electrically connected with each other, where each of the plurality of cell strings is the cell string described above. In some embodiments, based on the actual requirements, a plurality of cell strings may be connected in series and/or in parallel. The cell strings connected in series can help to increase the output voltage of the photovoltaic module, while the cell strings connected in parallel can help to increase the output current of the photovoltaic module.

Therefore, according to the present disclosure, at least one of the positive electrode and the negative electrode includes a plurality of sub-electrodes spaced apart from each other, so that the photovoltaic cell includes a plurality of sub-cells, and when the photovoltaic module is blocked, only one or some sub-cells do not generate electricity, thereby ensuring the electricity generation capacity of the photovoltaic module as much as possible while protecting the photovoltaic module, and achieving the optimal electricity generation effect and reliability.

The present disclosure has disclosed exemplary embodiments, and although specific terms are employed, they are used and should be interpreted merely in a generic and descriptive sense, not for purposes of limitation. In some instances, as would be apparent to one skilled in the art, features, characteristics and/or elements described in connection with a particular embodiment may be used alone or in combination with features, characteristics and/or elements described in connection with another embodiment, unless expressly stated otherwise. It will, therefore, be understood by those skilled in the art that various changes in form and details may be made therein without departing from the scope of the present disclosure as set forth in the appended claims.

What is claimed is:

1. A photovoltaic cell comprising:
a positive electrode and a negative electrode, wherein at least one of the positive electrode and the negative electrode comprises a plurality of sub-electrodes spaced apart from each other, so that the photovoltaic cell comprises a plurality of sub-cells connected in parallel, and each of the plurality of sub-electrodes serves as an electrode of a corresponding sub-cell of the plurality of sub-cells.

2. The photovoltaic cell according to claim 1, wherein the plurality of sub-electrodes are separated by a distance of 0.1 mm to 3 mm.

3. The photovoltaic cell according to claim 1, wherein a sub-electrode of the positive electrode comprises a positive busbar and positive finger lines electrically connected to the positive busbar.

4. The photovoltaic cell according to claim 3, wherein the positive finger lines in each sub-cell are separated from each other.

5. The photovoltaic cell according to claim 3, wherein every two positive finger lines in each sub-cell are connected end to end.

6. The photovoltaic cell according to claim 3, wherein every three or more or all positive finger lines in each sub-cell are connected end to end.

7. The photovoltaic cell according to claim 3, wherein the plurality of sub-electrodes are separated by a distance equal to a pitch between the positive finger lines.

8. The photovoltaic cell according to claim 1, wherein a sub-electrode of the negative electrode comprises a negative busbar and negative finger lines electrically connected to the negative busbar.

9. The photovoltaic cell according to claim 8, wherein the negative finger lines in each sub-cell are separated from each other.

10. The photovoltaic cell according to claim 8, wherein every two negative finger lines in each sub-cell are connected end to end.

11. The photovoltaic cell according to claim 8, wherein every three or more or all negative finger lines in each sub-cell are connected end to end.

12. The photovoltaic cell according to claim 8, wherein the plurality of sub-electrodes are separated by a distance equal to a pitch between the negative finger lines.

13. The photovoltaic cell according to claim 1, wherein when each of the positive electrode and the negative electrode comprises a plurality of sub-electrodes spaced apart from each other, the sub-electrodes of the positive electrode are arranged in one-to-one correspondence with the sub-electrodes of the negative electrode.

14. A cell string comprising a plurality of photovoltaic cells connected in series, wherein each of the photovoltaic cells comprises:
a positive electrode and a negative electrode, wherein at least one of the positive electrode and the negative electrode comprises a plurality of sub-electrodes spaced apart from each other, so that the photovoltaic cell comprises a plurality of sub-cells connected in parallel, and each of the plurality of sub-electrodes serves as an electrode of a corresponding sub-cell of the plurality of sub-cells.

15. The cell string according to claim 14, wherein a sub-electrode of the positive electrode comprises a positive busbar and positive finger lines electrically connected to the positive busbar.

16. The cell string according to claim 14, wherein a sub-electrode of the negative electrode comprises a negative busbar and negative finger lines electrically connected to the negative busbar.

17. A photovoltaic module comprising:
a plurality of cell strings electrically connected with each other, wherein each of the plurality of cell strings comprises a plurality of photovoltaic cells connected in series, and
each of the photovoltaic cells comprises: a positive electrode and a negative electrode, wherein at least one of the positive electrode and the negative electrode comprises a plurality of sub-electrodes spaced apart from each other, so that the photovoltaic cell comprises a plurality of sub-cells connected in parallel, and each of the plurality of sub-electrodes serves as an electrode of a corresponding sub-cell of the plurality of sub-cells.

18. The photovoltaic module according to claim 17, wherein a sub-electrode of the positive electrode comprises a positive busbar and positive finger lines electrically connected to the positive busbar.

19. The photovoltaic module according to claim 17, wherein a sub-electrode of the negative electrode comprises a negative busbar and negative finger lines electrically connected to the negative busbar.
